(19) United States
(12) Patent Application Publication
(10) Pub. No.: US 2026/0190663 A1
(43) Pub. Date: Jul. 2, 2026

(54) DISPLAY PANEL

(71) Applicant: LG Display Co., Ltd., Seoul (KR)

(72) Inventors: Jungjune Kim, Seoul (KR); Daehee Kim, Goyang-si (KR); Seunghee Nam, Paju-si (KR)

(21) Appl. No.: 19/372,163

(22) Filed: Oct. 28, 2025

(30) Foreign Application Priority Data
Dec. 26, 2024 (KR) 10-2024-0197663

(51) Int. Cl. H10K 59/124; H10K 59/12; H10K 59/122; H10K 59/80; H10K 59/88

(52) U.S. Cl. CPC H10K 59/124; H10K 59/1201; H10K 59/122; H10K 59/80521; H10K 59/88

(57) ABSTRACT

A display panel in which an organic insulating layer is disposed in a trench formed between adjacent sub-pixels and extends through a first inorganic insulating layer and a second inorganic insulating layer, thereby greatly elongating a path of horizontal leakage current between the adjacent sub-pixels formed on the organic insulating layer.

### CROSS REFERENCE TO RELATED APPLICATION

Pursuant to 35 U.S.C. § 119(a), this application claims the benefit of an earlier filing date and right of priority to Korean Patent Application No. 10-2024-0197663, filed Dec. 26, 2024, the entire contents of which is incorporated herein for all purposes by this reference.

### TECHNICAL FIELD

The present disclosure relates to a display panel.

### BACKGROUND

Display devices are implemented in a wide variety of forms, such as televisions, monitors, smartphones, tablet PC, laptops, wearable devices, etc.

An organic light-emitting display device (OLED) among display devices displaying various information as an image is a self-luminous device that emits light by itself, and has advantages in that a response speed is fast, light emission efficiency and luminance are high and a viewing angle is large, and a contrast ratio and color gamut are excellent.

Recently, as users' demands for high-quality images increase, development of high-resolution display devices is actively progressing.

### SUMMARY

A display panel according to a first aspect of the present disclosure includes: a substrate in which a plurality of sub-pixel areas corresponding to a plurality of sub-pixels are defined; a first inorganic insulating layer disposed on the substrate; a second inorganic insulating layer disposed on the first inorganic insulating layer; a trench formed between adjacent sub-pixels among the plurality of sub-pixels and extending through the first inorganic insulating layer and the second inorganic insulating layer; and an organic insulating layer disposed in the trench, wherein the first inorganic insulating layer includes a first extension portion extending inwardly toward the trench and into the organic insulating layer, wherein the second inorganic insulating layer includes a second extension portion extending inwardly toward the trench and into the organic insulating layer.

In accordance with some implementations of the first aspect, the first extension portion is upwardly spaced apart from the substrate by a predetermined distance.

In accordance with some implementations of the first aspect, at least a portion of an area between the first extension portion and the substrate is filled with the organic insulating layer.

In accordance with some implementations of the first aspect, the second extension portion is upwardly spaced apart from the first extension portion by a predetermined distance.

In accordance with some implementations of the first aspect, at least a portion of an area between the second extension portion and the first extension portion is filled with the organic insulating layer.

In accordance with some implementations of the first aspect, each of the first extension portion and the second extension portion are disposed within the organic insulating layer without extending through and disconnecting the organic insulating layer.

In accordance with some implementations of the first aspect, the organic insulating layer continuously extends through the trench.

In accordance with some implementations of the first aspect, the organic insulating layer includes a stepped portion recessed downwardly, wherein a vertical level of a lowermost surface of the stepped portion is lower than a vertical level of the second extension portion.

In accordance with some implementations of the first aspect, the display panel further comprises a light-emitting element layer disposed on the organic insulating layer, wherein the light-emitting element layer continuously extends on and along the stepped portion so as to cover the trench.

In accordance with some implementations of the first aspect, at least one of the first extension portion or the second extension portion extends through the organic insulating layer so as to protrude out of the organic insulating layer.

In accordance with some implementations of the first aspect, the organic insulating layer is discontinuously disposed in the trench.

In accordance with some implementations of the first aspect, the display panel further comprises a light-emitting element layer disposed on the organic insulating layer, wherein the light-emitting element layer is discontinuously disposed in the trench.

In accordance with some implementations of the first aspect, the connection of the light-emitting element layer in the trench is interrupted by at least one of the first extension portion and the second extension portion.

In accordance with some implementations of the first aspect, at least one dummy light-emitting element layer is further disposed in the trench and is discontinuous from the light-emitting element layer.

In accordance with some implementations of the first aspect, the first inorganic insulating layer and the second inorganic insulating layer are in contact with the organic insulating layer.

A display panel according to a first aspect of the present disclosure includes: a substrate; a buffer layer disposed on the substrate; a circuit area disposed on the buffer layer; a passivation layer disposed on the circuit area; a first electrode disposed on the passivation layer; a bank layer disposed on the first electrode so as to define regions for a plurality of light emission areas; a light-emitting element layer disposed on the bank layer; and a second electrode disposed on the light-emitting element layer, wherein a discontinuous area is positioned between adjacent light emission areas, wherein each of the buffer layer and the passivation layer is discontinuous in the discontinuous area, wherein the bank layer is in contact with the buffer layer and the passivation layer in the discontinuous area.

In accordance with some implementations of the second aspect, an end portion of each of the buffer layer and the passivation layer extends into the bank layer in the discontinuous area.

In accordance with some implementations of the second aspect, an end portion of the buffer layer and an end portion of the passivation layer positioned in the discontinuous area are spaced apart from each other in a vertical direction.

In accordance with some implementations of the second aspect, each of the light-emitting element layer and the second electrode continuously extends on and along the bank layer in the discontinuous area, wherein a vertical level of a lowermost surface of a portion of each of the light-emitting element layer and the second electrode positioned in the discontinuous area is lower than a vertical level of a portion of the passivation layer positioned in the discontinuous area.

In accordance with some implementations of the second aspect, each of the light-emitting element layer and the second electrode is broken in the discontinuous area.

Implementations disclosed herein can provide one or more of the following technical effects.

According to an implementation of the present disclosure, the organic insulating layer may be disposed in the trench formed between adjacent ones of the plurality of sub-pixels and extending through the first inorganic insulating layer and the second inorganic insulating layer, which can have an effect of greatly elongating the horizontal leakage current path between neighboring sub-pixels formed on the organic insulating layer. Accordingly, the horizontal leakage current may be reduced.

In addition, according to an implementation of the present disclosure, the first extension portion of the first inorganic insulating layer and the second extension portion of the second inorganic insulating layer extend into the organic insulating layer, such that the moisture permeation path formed in the organic insulating layer may be formed as a complicated path bypassing one or more of the first extension portion and the second extension portion. Accordingly, this can significantly elongate the moisture permeation path in the organic insulating layer, and enhance the ability to cope with the moisture permeation of the display panel.

In addition, according to an implementation of the present disclosure, the first extension portion of the first inorganic insulating layer and the second extension portion of the second inorganic insulating layer may extend into the organic insulating layer, so that the organic insulating layer may be engaged with and bonded to the first extension portion and the second extension portion via their complex structure. This may prevent the material of the organic insulating layer from being loosened and lost even when an external force is applied to the display panel or during a long-term operation thereof, thereby improving the stability and durability of the display panel.

In addition, according to an implementation of the present disclosure, each of the first extension portion of the first inorganic insulating layer and the second extension portion of the second inorganic insulating layer may extend into the organic insulating layer, thereby allowing the inorganic layer and the organic layer made of different materials to be engaged with each other and bonded to each other. For example, when the inorganic layer and the organic layer are in contact with each other, the peel-off from each other may not easily occur, compared to when the inorganic layer and the inorganic layer are in contact with each other, or when the organic layer and the organic layer are in contact with each other. Accordingly, the removal of the inorganic layer and the organic layer from each other may be reduced, and thus the organic insulating layer may be prevented from being peeled off, thereby improving the stability and durability of the display panel.

As described above, the stability and durability of the display panel may be improved, such that the lifespan of the display panel may be improved to implement a low-power display panel, thereby reducing power consumption.

In addition, according to an implementation of the present disclosure, the first extension portion may be spaced apart from the substrate by a predetermined distance in the vertical direction, so that at least a portion of an area defined therebetween may be filled with the organic insulating layer. Accordingly, a multi-layered complex structure in which the organic insulating layer is interposed between the substrate and the first extension may be formed, so as to elongate a moisture permeation path and lower the possibility that the organic insulating layer is peeled off.

In addition, according to an implementation of the present disclosure, the second extension portion is spaced apart from the first extension portion by a predetermined distance in the vertical direction, such that at least a portion of an area therebetween may be filled with the organic insulating layer. Accordingly, a multilayer complex structure in which the organic insulating layer is interposed between the first extension portion and the second extension portion may be formed, thereby elongating the moisture permeation path and lowering the possibility that the organic insulating layer is peeled off.

In addition, according to an implementation of the present disclosure, the first extension portion and the second extension portion may be positioned in the organic insulating layer without extending through the organic insulating layer, such that an inorganic insulating barrier in a form trapped in the organic insulating layer may be formed. This can have the effect of elongating the moisture permeation path in the organic insulating layer, by implementing a complex structure in a maze-like form.

In addition, according to an implementation of the present disclosure, the organic insulating layer includes the stepped portion having the lowermost surface positioned at a vertical level lower than a vertical level of the second extension portion, which can have the effect of significantly elongating, in a vertical direction, the path of the horizontal leakage current between the neighboring sub-pixels formed on the organic insulating layer.

In addition, according to an implementation of the present disclosure, at least one of the first extension portion and the second extension portion may extend through the organic insulating layer and protrude out of the organic insulating layer, so that the organic insulating layer may be broken in the trench. Accordingly, the light-emitting element layer formed on the organic insulating layer may be broken in the trench, and thus, the path of the horizontal leakage current between the neighboring sub-pixels may be directly cut off.

Effects of the present disclosure are not limited to the effects mentioned above, and other effects not mentioned will be clearly understood by those skilled in the art from the description as set forth below. In addition to the above effects, specific effects of the present disclosure are described together while describing specific details for carrying out the present disclosure.

### BRIEF DESCRIPTION OF DRAWINGS

FIG. 1 is a schematic plan view of an example of a display panel.

FIG. 2 is a cross-sectional view of an example of an area A of FIG. 1 according to an implementation.

FIG. 3 is a cross-sectional view of an example of an area I-I′ of FIG. 2 according to an implementation.

FIG. 4 is a cross-sectional view of an example of an area I-I′ of FIG. 2 according to another implementation.

FIG. 5 is a cross-sectional view of an example of an area I-I′ of FIG. 2 according to still another implementation.

FIG. 6 is a cross-sectional view of an example of an area I-I′ of FIG. 2 according to still yet another implementation.

FIG. 7 is a cross-sectional view of an example of an area I-I′ of FIG. 2 according to still yet another implementation.

FIGS. 8 to 11 are process cross-sectional views sequentially illustrating examples of a process of forming a first inorganic insulating layer, a second inorganic insulating layer, and an organic insulating layer according to FIG. 4.

### DETAILED DESCRIPTION

As users' demands for a high-resolution display device increase, display devices are produced with increased density of sub-pixels and smaller spacing between the sub-pixels. However, as the distance between sub-pixels decreases, this can result in increased horizontal leakage current generated between sub-pixels adjacent to each other in the horizontal direction, thereby causing distortion of pixel information and deterioration of reliability and image quality of the display panel.

Various techniques can be considered in order to reduce the generation of the horizontal leakage current, all of which have their respective disadvantages.

For example, increasing the distance between the sub-pixels may allow a direct path through which a horizontal leakage current may flow to be lengthened. However, such a method sacrifices the resolution or integration of the display panel, and thus there is a problem in that it is difficult to implement a high-resolution display panel.

In addition, a method of increasing the leakage current path may be attempted by a method of patterning a portion of each of some organic material layers, such as a planarization layer disposed in the display panel. However, there is a limit to increasing the path of the leakage current only by patterning each of some organic material layers as described above.

In addition, the organic material layer in the display panel may also act as a permeation path of external substances such as moisture and oxygen. When the external substance penetrates into the display panel, the light-emitting element layer may deteriorate, and the performance of various organic material layers may deteriorate, thereby deteriorating the reliability and shortening the lifespan of the display panel.

Accordingly, implementations of the present disclosure can help mitigate one or more of the problems described above. Some examples of possible technical benefits of the implementations disclosed herein are described below.

Implementations of the present disclosure can provide a display panel capable of reducing the generation of the horizontal leakage current and enhancing moisture barrier performance through various experiments.

Implementations of the present disclosure can provide a display panel capable of reducing a horizontal leakage current between neighboring sub-pixels.

In some implementations, a display panel is capable of improving moisture barrier reliability of the display panel.

In some implementations, a display panel is capable of preventing a material of an organic insulating layer from being lost.

In some implementations, a display panel is capable of reducing peeling off of an inorganic layer and an organic layer from each other.

In some implementations, a display panel is capable of increasing a moisture permeation path and reducing the possibility of peeling off of an organic insulating layer.

In some implementations, a display panel is capable of increasing a moisture permeation path in an organic insulating layer in a complex form such as a maze.

In some implementations, a display panel is capable of greatly increasing a path of a horizontal leakage current between neighboring sub-pixels in a vertical direction.

In some implementations, a display panel is capable of directly blocking a path of a horizontal leakage current between neighboring sub-pixels.

Technical benefits of implementations of the present disclosure are not limited to the above-described benefits. Other benefits and advantages according to the present disclosure that are not mentioned may be understood based on following descriptions, and may be more clearly understood based on implementations according to the present disclosure. Further, it will be easily understood that the advantages according to implementations of the present disclosure may be realized using means shown in the claims or combinations thereof.

Advantages and features of the present disclosure, and a method of achieving the advantages and features will become apparent with reference to implementations described below in detail together with the accompanying drawings. However, the present disclosure is not limited to the implementations as disclosed under, but may be implemented in various different forms. Thus, these implementations are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various implementations are illustrated and described further below. It will be understood that the description herein is not intended to limit the claims to the specific implementations described. On the contrary, it is intended to cover alternatives, modifications, and equivalents as may be included within the spirit and scope of the present disclosure as defined by the appended claims. A shape, a size, a ratio, an angle, a number, etc. disclosed in the drawings for illustrating implementations of the present disclosure are illustrative, and the present disclosure is not limited thereto. The terminology used herein is directed to the purpose of describing particular implementations only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

In interpretation of numerical values, an error or tolerance therein may occur even when there is no explicit description thereof. In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween. Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated. When a certain implementation may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved. It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an implementation may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations. The features of the various implementations of the present disclosure may be partially or entirely combined with each other, and may be technically associated with each other or operate with each other. The implementations may be implemented independently of each other and may be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, “implementations,” “examples,” “aspects, etc. should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating implementations. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions. In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified. As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

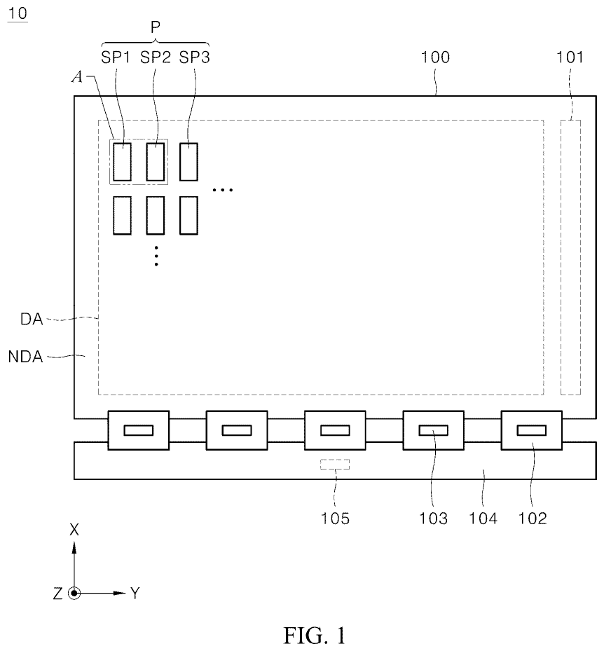

FIG. 1 illustrates an example of a display panel and a display device according to an implementation of the present disclosure. A display panel 10 described below is implemented as an organic electroluminescence display panel (Organic Light Emitting Diodes Display Panel) by way of example. However, implementations of the present disclosure are not limited thereto. In addition, the display panel 10 according to an implementation of the present disclosure may be embodied as various types of display devices, and the type of the display device is not particularly limited.

The display panel 10 may include a substrate 100 including a display area DA and a non-display area NDA outside (e.g., surrounding) a periphery of the display area DA. The display panel 10 may include a substrate 100, a source driving integrated circuit (IC) 103, a flexible film 102, a circuit board 104, and a timing controller 105.

The display area DA on the substrate 100 may include a plurality of sub-pixels SP1, SP2, and SP3 respectively formed in areas in which a plurality of data lines extending in a first direction and a plurality of gate lines extending in a second direction intersecting the first direction intersect each other. The first direction described herein may be an X-axis direction, the second direction may be a Y-axis direction, and the Z-axis direction may be a direction perpendicular to a plane defined by the X-axis and the Y-axis. In addition, in the present disclosure, one pixel P is configured to include the first sub-pixel SP1, the second sub-pixel SP2, and the third sub-pixel SP3. However, implementations of the present disclosures are not limited thereto, and additional sub-pixels may be further included in one pixel P.

For example, the sub-pixels SP1, SP2, and SP3 may be implemented to emit light of different colors, such as red, green, and blue light beams, respectively. Hereinafter, the first sub-pixel SP1 is a red sub-pixel that emits light of red, the second sub-pixel SP2 is a green sub-pixel that emits light of green, and the third sub-pixel SP3 is a blue sub-pixel that emits light of blue. The plurality of sub-pixels SP1, SP2, and SP3 may be arranged in a matrix form arranged in a plurality of rows and columns. The plurality of sub-pixels may further include a white sub-pixel that emits light of white.

A gate driver 101 positioned on one side or each of both opposing sides of the display area DA may be disposed in the non-display area NDA on the substrate 100. The gate driver 101 may be implemented in a Gate-in-panel (GIP) manner. The gate driver 101 may supply gate signals to gate lines according to a gate control signal input from the timing controller 105.

The source driving integrated circuit 103 may receive digital video data and a source control signal from the timing controller 105. The source driving integrated circuit 103 may convert digital video data into analog data voltages according to the source control signal and supply the analog data voltages to the data lines. The source driving integrated circuit 103 may be manufactured as a driving chip of a chip on film (COF) or chip on plastic (COP) type and may be mounted on a plurality of flexible films 102. The circuit board 104 may be attached to the plurality of flexible films 102. A plurality of circuits embodied as driving chips such as the timing controller 105 may be mounted on the circuit board 104.

The timing controller 105 may receive the digital video data and a timing signal from an external system board through a cable of the circuit board 104. The timing controller 105 may supply the gate control signal for controlling an operation timing of the gate driver 101 and the source control signal for controlling the source driving integrated circuits 103 based on the timing signal.

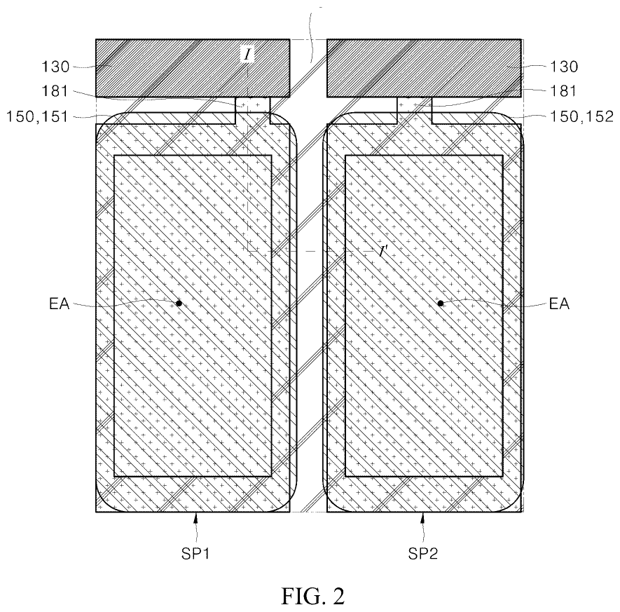

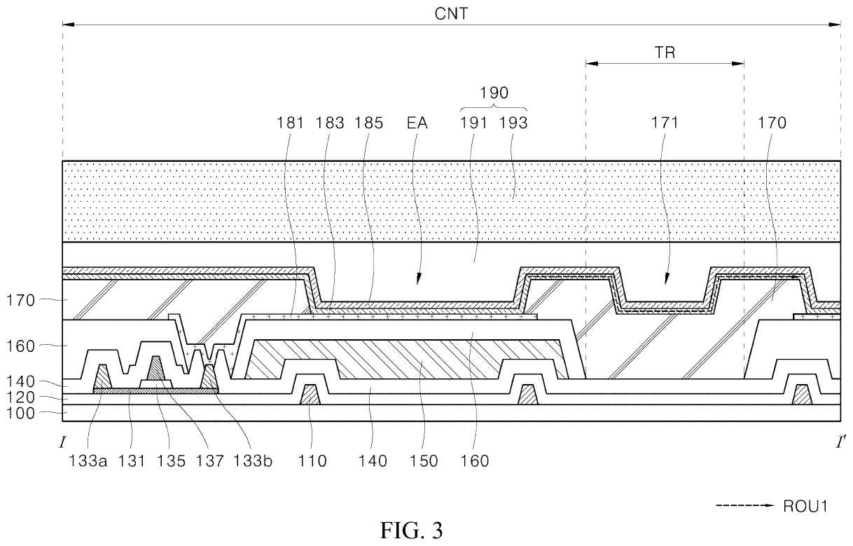

FIGS. 2 and 3 illustrate examples of a stacked structure of the display panel 10 according to an implementation of the present disclosure. In FIGS. 2 and 3, the first sub-pixel SP1 and the second sub-pixel SP2 adjacent to each other will be described by way of example. FIG. 2 is a cross-sectional view of an area A of FIG. 1 according to an implementation, and FIG. 3 is a cross-sectional view of an area I-I′ of FIG. 2 according to an implementation.

The display panel 10 may include the substrate 100. The substrate 100 may be made of glass or plastic such as polyimide. However, implementations of the present disclosure are not limited thereto, and the substrate 100 may be made of a semiconductor material such as a silicon wafer. For example, the substrate 100 may be embodied as a single crystal silicon wafer formed by growing single crystal silicon (Si) or may be embodied as a wafer made of various semiconductor materials.

A light-blocking layer 110 may be disposed on the substrate 100. For example, the light-blocking layer 110 may be disposed to overlap a color filter layer 150 to be described later in the vertical direction. In addition, the light-blocking layer 110 may be positioned at a boundary of a light emission area EA formed on the color filter layer 150. The light-blocking layer 110 may prevent a color of light that is emitted from the light emission area EA of one sub-pixel and passes through the color filter layer 150 from being mixed with a color of light emitted from the light emission area EA of another sub-pixel adjacent thereto. For example, the light-blocking layer 110 may be made of a metal material such as copper (Cu), aluminum (Al), titanium (Ti), and molybdenum (Mo), or may be formed as a stacked structure of metal material layers such as copper/molybdenum-titanium layer (Cu/MoTi), titanium layer/aluminum layer/titanium layer (Ti/Al/Ti), or the like. However, implementations of the present disclosure are not limited thereto.

A first inorganic insulating layer 120, which can be a buffer layer, may be disposed on the light-blocking layer 110. The first inorganic insulating layer 120 may be disposed to cover an entire surface of the substrate 100. The first inorganic insulating layer 120 may reduce penetration of moisture or impurities through the substrate 100. The first inorganic insulating layer 120 may include at least one inorganic material. For example, the first inorganic insulating layer 120 may be formed as a single layer or a stack of multiple layers made of silicon oxide (SiOx) or silicon nitride (SiNx). However, implementations of the present disclosure are not limited thereto.

A circuit area 130 may be disposed on the first inorganic insulating layer 120. For example, the circuit area 130 may include a thin-film transistor. The thin-film transistor may be a driving thin-film transistor or a switching thin-film transistor. The thin-film transistor may include an active layer 131, a source electrode 133a, a drain electrode 133b, and a gate electrode 137.

For example, the active layer 131 may be disposed on the first inorganic insulating layer 120. The source electrode 133a and the drain electrode 133b may be disposed on one side and the other side of the active layer 131, respectively, so as to be spaced apart from each other. The positions of the source electrode 133a and the drain electrode 133b may be interchanged with each other. A gate insulating layer 135 patterned in a predetermined pattern may be disposed on the active layer 131. The gate electrode 137 may be disposed on the gate insulating layer 135. Each of the source electrode 133a, the drain electrode 133b, and the gate electrode 137 may be made of a metal material such as copper (Cu), aluminum (Al), titanium (Ti), or molybdenum (Mo), or may be formed as a stacked structure of metal material layers such as copper layer/molybdenum-titanium layer (Cu/MoTi), titanium layer/aluminum layer/titanium layer (Ti/Al/Ti). However, implementations of the present disclosure are not limited thereto.

A second inorganic insulating layer 140 (e.g., a passivation layer) may be disposed on the circuit area 130. The second inorganic insulating layer 140 may be disposed to cover the entire surface of the substrate 100. The second inorganic insulating layer 140 may include at least one inorganic material. In addition, the second inorganic insulating layer 140 may be referred to as an interlayer insulating layer. For example, the second inorganic insulating layer 140 may be formed as a single layer or a multilayer made of silicon oxide (SiOx) or silicon nitride (SiNx). However, implementations of the present disclosure are not limited thereto.

As described above, the first inorganic insulating layer 120 (e.g., a buffer layer) and the second inorganic insulating layer 140 (e.g., a passivation layer) may continuously extend across the entire surface of the substrate 100. An area in which the first inorganic insulating layer 120 and the second inorganic insulating layer 140 continuously extend may be defined as a continuous area CNT.

The color filter layer 150 may be disposed on the second inorganic insulating layer 140. The color filter layer 150 may be disposed to be spaced apart from the circuit area 130 by a predetermined distance in a horizontal direction. The color filter layer 150 may be disposed to overlap the light emission area EA to be described later in the vertical direction. The color filter layer 150 may be formed to allow light of different colors to be emitted from different sub-pixels. For example, a red first color filter layer 151 may be disposed in the first sub-pixel SP1, a green second color filter layer 152 may be disposed in the second sub-pixel SP2, and a blue color filter layer may be disposed in the third sub-pixel SP3. When the white sub-pixel is additionally disposed, a separate color filter layer may not be disposed in the white sub-pixel SP.

An overcoat layer 160 may be disposed on the color filter layer 150. The overcoat layer 160 may be disposed to cover the entire surface of the substrate 100. The overcoat layer 160 may reduce a step caused by an underlying structure. Accordingly, the overcoat layer 160 may be referred to as a planarization layer. The overcoat layer 160 may include an organic material. For example, the overcoat layer 160 may include an organic material such as photoacryl, polyimide, benzocyclobutene series resin, acrylate, or the like.

A trench TR may be formed at a boundary between adjacent sub-pixels. The trench TR may be formed by removing a partial area of the overcoat layer 160. For example, the trench TR may be formed in the overcoat layer 160 in the form of a concave groove recessed downwardly so as to have a predetermined horizontal width and vertical length. The trench TR is an area in which a partial area of the overcoat layer 160 is patterned, and may be referred to as a patterned area.

A first electrode 181 may be disposed on the overcoat layer 160. The first electrode 181 may be referred to as a pixel electrode. The first electrode 181 may also be referred to as an anode electrode. The first electrode 181 may be electrically connected to the drain electrode 133b via a contact hole extending through the second inorganic insulating layer 140 and the overcoat layer 160. For example, the first electrode 181 may include a transparent conductive material such as indium tin oxide (ITO), indium zinc oxide (IZO), and zinc oxide (ZnO).

Each of the first electrodes 181 may be disposed between adjacent sub-pixels. The first electrodes 181 may be disposed to be spaced apart from each other. An organic insulating layer 170, such as a bank layer, may be disposed on the first electrode 181. The organic insulating layer 170 may be formed to cover an end of the first electrode 181, thereby preventing current from being concentrated on the end of the first electrode 181. In addition, the organic insulating layer 170 may substantially define a boundary of the light emission area EA through which light is emitted. Accordingly, an area in which the organic insulating layer 170 is partially removed to expose an upper surface of the first electrode 181 may be defined as the light emission area EA.

The organic insulating layer 170 may include at least one organic material. For example, the organic insulating layer 170 may include an organic material such as photoacryl, polyimide, benzocyclobutene series resin, acrylate, or the like. In addition, the organic insulating layer 170 may be referred to as a fence. In addition, the organic insulating layer 170 may be embodied as a black bank including a black material.

A light-emitting element layer 183 may be disposed on the first electrode 181. The light-emitting element layer 183 disposed on the first electrode 181 may be formed over the entire surface of the substrate 100 so as to cover the sub-pixels adjacent to each other and the organic insulating layer 170. The light-emitting element layer 183 may be formed as a single stack. However, implementations of the present disclosures are not limited thereto, and the light-emitting element layer 183 may have a tandem structure including two stacks in which a first stack, a charge generation layer (CGL), and a second stack are sequentially stacked, or a tandem structure including three or more stacks.

For example, when the light-emitting element layer 183 includes the first stack, the charge generation layer, and the second stack, the first stack may include a hole injection layer (HIL), a hole transport layer (HTL), a light-emitting material layer (EML), and an electron transport layer (ETL). The light-emitting material layer (EML) of the first stack may emit one of red light, green light, blue light, and yellow light. The charge generation layer (CGL) may include a negative-type charge generation layer (CGL) for supplying electrons to the first stack, and a positive-type charge generation layer (CGL) for supplying holes to the second stack. The second stack may include a hole transport layer (HTL), a light-emitting material layer (EML), an electron transport layer (ETL), and an electron injection layer (EIL). The light-emitting material layer (EML) of the second stack may emit one of red light, green light, blue light, and yellow light. The light-emitting material layer (EML) of the first stack and the light-emitting material layer (EML) of the second stack emit light of different colors, so that the light-emitting element layer 183 including the first stack and the second stack may emit white light.

The second electrode 185 may be disposed on the light-emitting element layer 183. The second electrode 185 may be formed over the entire surface of the substrate 100 and may be electrically connected to the light-emitting element layer 183 formed to cover all sub-pixels. The second electrode 185 may be referred to as a common electrode. In addition, the second electrode 185 may be referred to as a cathode electrode. For example, the second electrode 185 may include magnesium (Mg), calcium (Ca), aluminum (Al), silver (Ag), or an alloy thereof. However, implementations of the present disclosure are not limited thereto.

In the light emission area EA defined by the organic insulating layer 170 (e.g., a bank layer), the first electrode 181, the light-emitting element layer 183, and the second electrode 185 may be sequentially stacked and may be in contact with and overlap each other to emit light. Light emitted from the light emission area EA may be white light. Light emitted from the light emission area EA may be emitted toward the color filter layer 150 disposed thereunder. Therefore, the display panel 10 according to an implementation of the present disclosure may operate in a bottom emission manner in which light is emitted downwardly toward the substrate 100.

An encapsulation structure 190 that blocks external moisture and oxygen may be disposed on the second electrode 185. For example, the encapsulation structure 190 may include an adhesive layer 191 and an encapsulation layer 193. The adhesive layer 191 fixes the encapsulation layer 193 and may also perform a sealing function. For example, the encapsulation layer 193 may be a metal encapsulation layer.

As described above, referring to FIG. 3, at least a partial area is patterned and removed in the overcoat layer 160 in the boundary between the sub-pixels adjacent to each other such that the trench TR may be formed. An upper surface of the second inorganic insulating layer 140 may be exposed to the outside through the trench TR. As the organic insulating layer 170 is disposed in the trench TR formed as described above, a stepped portion 171 recessed downwardly so as to have a predetermined depth may be formed in the organic insulating layer 170. The lowermost surface of the stepped portion 171 may be disposed to be spaced apart from the upper surface of the second inorganic insulating layer 140 by a predetermined distance. Accordingly, the lowermost surface of the stepped portion 171 may be positioned at a higher vertical level than a vertical level of the upper surface of the second inorganic insulating layer 140. Preferably, the vertical level of the lowermost surface of the stepped portion 171 may be higher than a vertical level of the upper surface of the overcoat layer 160.

Because the stepped portion 171 is formed in the organic insulating layer 170 (which can be a bank layer), an upper surface of the organic insulating layer 170 has a bent shape. Accordingly, the light-emitting element layer 183 and the second electrode 185 formed on the organic insulating layer 170 also have a bent shape, conforming to the shape of the upper surface of the organic insulating layer 170. Moreover, the light-emitting element layer 183 and the second electrode 185 continuously extend on and along the stepped portion 171. Accordingly, a path ROU1 of the horizontal leakage current that may occur via the light-emitting element layer 183 between adjacent sub-pixels is lengthened, and thus the horizontal leakage current can be reduced.

However, in some scenarios, there is a limit in the amount of reduction in the horizontal leakage current, simply based on the shape of the stepped portion 171 of the organic insulating layer 170 alone. In addition, it may still be difficult to solve the problem of moisture permeation that may occur through the organic insulating layer 170. In addition, it may be difficult to solve the problem that the organic insulating layer 170 formed in the trench TR is peeled off and the material thereof is lost.

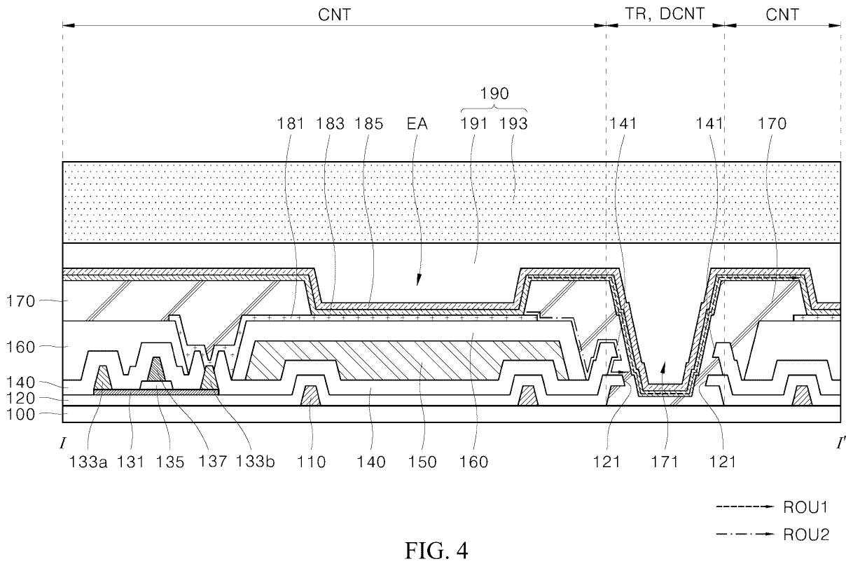

FIGS. 4 to 11 illustrate examples of additional implementations which are capable of further increasing the path of the horizontal leakage current, increasing the moisture permeation path, and preventing the loss of the material of the organic insulating layer 170. The description of FIGS. 4 to 11 below will focus on the differences compared to the implementations described above with reference to FIGS. 1 to 3, and thus, some redundant descriptions will be omitted.

Referring to FIG. 4, the first inorganic insulating layer 120 (e.g., a buffer layer), the second first inorganic insulating layer 140 (e.g., a passivation layer), the overcoat layer 160, and the organic insulating layer 170 (e.g., a bank layer) may be disposed on the substrate 100. In an implementation as described below, the first inorganic insulating layer 120 can be a buffer layer, the second inorganic insulating layer 140 can be a passivation layer, and the organic insulating layer 170 can be a bank layer. However, in another implementation, the first inorganic insulating layer 120 and the second inorganic insulating layer 140 may refer to other inorganic insulating layers made of inorganic materials, in addition to the buffer layer and the passivation layer, respectively. Further, the organic insulating layer 170 may refer to other organic insulating layers made of organic materials as another layer in addition to the bank layer.

In this example, the trench TR formed between adjacent sub-pixels may extend through the overcoat layer 160. The trench TR may be formed to further extend through the first inorganic insulating layer 120 and the second inorganic insulating layer 140 formed under the overcoat layer 160. Accordingly, in the trench TR defined between adjacent sub-pixels, each of the first inorganic insulating layer 120, the second inorganic insulating layer 140, and the overcoat layer 160 may be broken by discontinuities. As described above, each of the first inorganic insulating layer 120, the second inorganic insulating layer 140, and the overcoat layer 160 may be broken in the area between the adjacent sub-pixels, such that the trench TR may include a discontinuous area DCNT of each of the first inorganic insulating layer 120 and the second inorganic insulating layer 140. In the trench TR, the substrate 100 may be exposed to the outside. An area other than the discontinuous area DCNT may be the continuous area CNT. Each of the first inorganic insulating layer 120 and the second inorganic insulating layer 140 may continuously extend in the continuous area CNT.

Within the trench TR, a portion of the first inorganic insulating layer 120 and a portion of the second inorganic insulating layer 140 may each extend inward and protrude towards the trench TR. The portion of the first inorganic insulating layer 120 that extends and protrudes inwards toward the trench TR is referred to herein as a first extension portion 121. Similarly, the portion of the second inorganic insulating layer 140 that extends and protrudes inward toward the trench TR is referred to as a second extension portion 141. For example, the first and second extension portions 121 and 141 can extend inward on both sides of the trench TR. Accordingly, the first extension portion 121 of the first sub-pixel SP1 and the first extension portion 121 of the second sub-pixel SP2 may be spaced apart from each other by a predetermined distance and may extend so as to face each other. In addition, the second extension portion 141 of the first sub-pixel SP1 and the second extension portion 141 of the second sub-pixel SP2 may be spaced apart from each other by a predetermined distance and may extend so as to face each other. In some implementations, each of the first extension portion 121 and the second extension portion 141 may be formed to protrude further inward towards the trench TR beyond a side surface of the overcoat layer 160, as shown in FIG. 4.

Moreover, in some implementations, the first extension portion 121 and second extension portion 141 may also be raised in an upward direction, as shown in FIG. 4 and described below.

The first extension portion 121 of the first inorganic insulating layer 120 disposed on the substrate 100 may be spaced apart from the substrate 100 by a predetermined distance in an upward direction. For example, at least a portion of the first inorganic insulating layer 120 except for the first extension portion 121 may be in contact with the substrate 100. An end portion of the first inorganic insulating layer 120 spaced apart from the substrate 100 by a predetermined distance may be the first extension portion 121. A point from which the first extension portion 121 starts to extend may be defined as a boundary of the discontinuous area DCNT of the first inorganic insulating layer 120.

The first extension portion 121 may include at least one area extending in a vertical direction and an area extending in a horizontal direction. In addition, the first extension portion 121 may further include an area extending so as to have an inclined surface. The first extension portion 121 may be formed in a general shape obliquely upwardly inwardly of the trench TR. In addition, one or more steps may be formed in the shape of the first extension portion 121.

Similarly, the second extension portion 141 of the second inorganic insulating layer 140 disposed on the first inorganic insulating layer 120 may be spaced apart from the first inorganic insulating layer 120 by a predetermined distance in an upward direction. For example, at least a portion of the second inorganic insulating layer 140 except for the second extension portion 141 may be in contact with the first inorganic insulating layer 120. An end portion of the second inorganic insulating layer 140 spaced apart from the first inorganic insulating layer 120 by a predetermined distance may be the second extension portion 141. Accordingly, the end portion of the first inorganic insulating layer 120 and the end portion of the second inorganic insulating layer 140 may be spaced apart from each other in the vertical direction. In addition, the second extension portion 141 may be spaced apart from the side surface of the overcoat layer 160 facing the trench TR by a predetermined distance. A point from which the second extension portion 141 starts to extend may be defined as a boundary of the discontinuous area DCNT of the second inorganic insulating layer 140.

The second extension portion 141 may include at least one area extending in the vertical direction and an area extending in the horizontal direction. In addition, the second extension portion 141 may further include an area extending so as to have an inclined surface. The second extension portion 141 may be formed in a general shape obliquely upwardly inwardly of the trench TR. In addition, one or more steps may be formed in the shape of the second extension portion 141.

The organic insulating layer 170 may be disposed in the trench TR formed as described above. For example, the organic insulating layer 170 may be formed to fill a portion of the trench TR. As described above, the trench TR is formed to extend through the first inorganic insulating layer 120, the second inorganic insulating layer 140, and the overcoat layer 160. As such, the organic insulating layer 170 may be formed to contact the substrate 100, the first inorganic insulating layer 120, the second inorganic insulating layer 140, and the overcoat layer 160. For example, at least a partial area between the first extension portion 121 and the substrate 100 may be filled with the organic insulating layer 170. In addition, at least a partial area between the second extension portion 141 and the first extension portion 121 may be filled with the organic insulating layer 170. In addition, at least a partial area between the second extension portion 141 and the overcoat layer 160 may be filled with the organic insulating layer 170.

As such, the organic insulating layer 170 may be in contact with each of the first inorganic insulating layer 120, the second inorganic insulating layer 140, and the overcoat layer 160 in the discontinuous area DCNT of each of the first inorganic insulating layer 120, the second inorganic insulating layer 140, and the overcoat layer 160 formed in the trench TR. At least a partial area of each of the first extension portion 121 and the second extension portion 141 may be positioned in the discontinuous area DCNT. Accordingly, a partial area of each of the first inorganic insulating layer 120 (e.g., a buffer layer) and the second inorganic insulating layer 140 (e.g., a passivation layer) may be positioned in the discontinuous area DCNT.

As described above, according to an implementation of the present disclosure, the first extension portion 121 may be spaced apart from the substrate 100 by a predetermined distance in the vertical direction, so that at least a portion of an area defined therebetween may be filled with the organic insulating layer 170. Accordingly, a multi-layered complex structure in which the organic insulating layer 170 is interposed between the substrate 100 and the first extension portion 121 may be formed, so as to elongate a moisture permeation path ROU2 and the lower the possibility that the organic insulating layer 170 is peeled off.

In addition, according to an implementation of the present disclosure, the second extension portion 141 may be spaced apart from the first extension portion 121 by a predetermined distance in the vertical direction, so that at least a portion of an area defined therebetween may be filled with the organic insulating layer 170. Accordingly, a multi-layered complex structure in which the organic insulating layer 170 is interposed between the first extension portion 121 and the second extension portion 141 may be formed. This can have the effect of elongating the moisture permeation path ROU2 and lowering the possibility that the organic insulating layer is peeled off.

The organic insulating layer 170 may continuously extend in the trench TR. Therefore, the upper surface of the substrate 100 exposed through the trench TR may be covered with the organic insulating layer 170. In some implementations, since the trench TR is formed to extend through not only the overcoat layer 160 but also the first inorganic insulating layer 120 and the second inorganic insulating layer 140, a depth of the trench TR may be greater than that of the trench TR extending through only the overcoat layer 160 as described with reference to FIG. 3. Therefore, a stepped portion 171 recessed downwardly so as to have a predetermined depth may be formed in the organic insulating layer 170 in the trench TR. In this case, the stepped portion 171 may be recessed downwardly so as to have a depth greater than that of the stepped portion 171 as described with reference to FIG. 3. A vertical level of the lowermost surface of the stepped portion 171 may be lower than a vertical level of the upper surface of the overcoat layer 160. For example, the vertical level of the lowermost surface of the stepped portion 171 may be lower than a vertical level of the second extension portion 141. As another example, the vertical level of the lowermost surface of the stepped portion 171 may be lower than a vertical level of the first extension portion 121.

As described above, according to an implementation of the present disclosure, the organic insulating layer 170 includes the stepped portion 171 having the lowermost surface positioned at the vertical level lower than the vertical level of the upper surface of the overcoat layer 160. This can have the effect of significantly elongating, in the vertical direction, the path ROU1 of the horizontal leakage current defined between the neighboring sub-pixels formed on the organic insulating layer 170.

In some implementations, each of the light-emitting element layer 183 and the second electrode 185 may continuously extend on and along the organic insulating layer 170 in the discontinuous area DCNT of the first inorganic insulating layer 120 and the second inorganic insulating layer 140 formed in the trench TR. Accordingly, the lowermost surface of a portion of each of the light-emitting element layer 183 and the second electrode 185 positioned in the discontinuous area DCNT may be positioned at a vertical level lower than a vertical level of the upper surface of the overcoat layer 160. For example, the lowermost surface of the portion of each of the light-emitting element layer 183 and the second electrode 185 positioned in the discontinuous area DCNT may be positioned at a vertical level lower than a vertical level of the second extension portion 141. Accordingly, the lowermost surface of the portion of each of the light-emitting element layer 183 and the second electrode 185 positioned in the discontinuous area DCNT may be positioned at a vertical level lower than a vertical level of the portion of the second inorganic insulating layer 140 positioned in the discontinuous area DCNT. As another example, the lowermost surface of the portion of each of the light-emitting element layer 183 and the second electrode 185 positioned in the discontinuous area DCNT may be positioned at a vertical level lower than a vertical level of the first extension portion 121.

In some implementations, the stepped portion 171 having a relatively greater depth is formed in the organic insulating layer 170, and therefore the upper surface of the organic insulating layer 170 may be formed to be abruptly bent in the vertical direction. Accordingly, each of the light-emitting element layer 183 and the second electrode 185 formed on the organic insulating layer 170 may also be formed to be abruptly bent in the vertical direction in a conformal manner to the shape of the upper surface of the organic insulating layer 170. Each of the light-emitting element layer 183 and the second electrode 185 may continuously extend on and along the stepped portion 171. Accordingly, this can have the effect of greatly elongating the path ROU1 of the horizontal leakage current that may occur between the sub-pixels adjacent to each other via the light-emitting element layer 183, and thus more effectively reduce the horizontal leakage current.

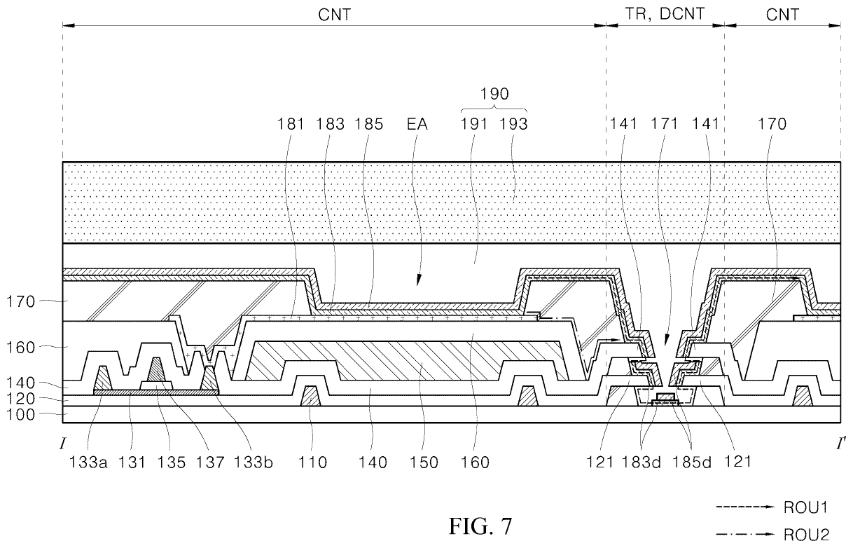

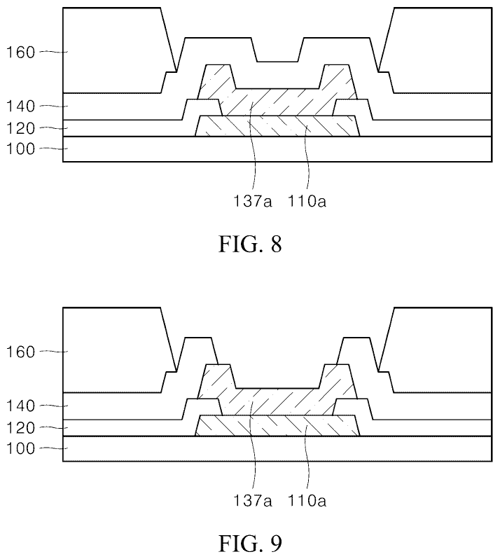

FIGS. 8 to 11 illustrate examples of a process of forming the first inorganic insulating layer 120, the second inorganic insulating layer 140, and the organic insulating layer 170 according to an implementation of the present disclosure in an area adjacent to the trench TR.

Referring to FIG. 8, a first metal layer 110a may be formed on the substrate 100. For example, the first metal layer 110a may be made of the same material as that of and may be formed in the same layer as that of and in the same process as that of the light-blocking layer 110. The first inorganic insulating layer 120 may be formed on the first metal layer 110a. The first inorganic insulating layer 120 may be disposed to cover an end of the first metal layer 110a such that the upper surface of the first metal layer 110a is exposed to the outside. In some implementations, the first inorganic insulating layer 120 may be disposed in the same layer as that of the first metal layer 110a, while an end of the first inorganic insulating layer 120 covering the end of the first metal layer 110a may be positioned at the vertical level higher than that of the first metal layer 110a. Accordingly, the first inorganic insulating layer 120 disposed to cover the end of the first metal layer 110a may be formed to have a step.

A second metal layer 137a may be formed on the first inorganic insulating layer 120. For example, the second metal layer 137a may be made of the same material as that of and may be formed in the same layer as that of and in the same process as that of the gate electrode 137. The second metal layer 137a may be disposed to cover the upper surface of the first metal layer 110a which is not covered with the first inorganic insulating layer 120 and is exposed to the outside, and to cover the end portion of the first inorganic insulating layer 120 disposed on the upper surface of the first metal layer 110a. In some implementations, a lower surface of the second metal layer 137a may be in contact with the upper surface of the first metal layer 110a such that the end of the second metal layer 137a may be disposed to cover the end of the first inorganic insulating layer 120 positioned on the upper surface of the first metal layer 110a. Therefore, the second metal layer 137a may be formed to have a step.

The second inorganic insulating layer 140 may be disposed on the second metal layer 137a. The second inorganic insulating layer 140 may be formed to cover the entire surface of the substrate 100. The overcoat layer 160 may be formed on the second inorganic insulating layer 140. The overcoat layer 160 may be patterned such that a portion of the upper surface of the second inorganic insulating layer 140 disposed in an area overlapping the first metal layer 110a and the second metal layer 137a in the vertical direction is exposed to the outside.

Referring to FIG. 9, a partial area of the second inorganic insulating layer 140 covering the upper surface of the second metal layer 137a may be patterned to be removed. Accordingly, the upper surface of the second metal layer 137a may be exposed to the outside. In this regard, the end of the second inorganic insulating layer 140 covering the end of the second metal layer 137a may not be removed. Accordingly, the end of the patterned second inorganic insulating layer 140 is disposed on the upper surface of the end of the second metal layer 137a, such that the end of the second inorganic insulating layer 140 may be formed to have a step.

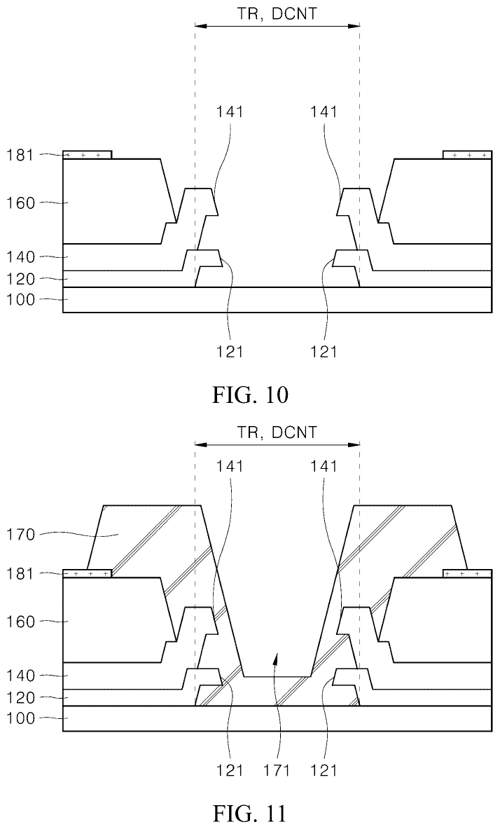

Referring to FIG. 10, the first electrode 181 may be disposed on the overcoat layer 160. The respective first electrodes 181 in adjacent sub-pixels may be spaced apart from each other. For example, the first electrode 181 may be made of indium tin oxide (ITO). In this case, the first electrode 181 may be patterned by etching indium tin oxide (ITO). In addition, each of the first metal layer 110a and the second metal layer 137a may be formed as a stack of copper layer/molybdenum-titanium layer (Cu/MoTi). In this case, each of the first metal layer 110a and the second metal layer 137a may be selectively removed by etching the copper layer/molybdenum-titanium layer (Cu/MoTi). Selectively removing only the first metal layer 110a and the second metal layer 137a as described above may allow the trench TR exposing the upper surface of the substrate 100 to the outside to be formed in the overcoat layer 160.

Since each of the first inorganic insulating layer 120 and the second inorganic insulating layer 140 is broken in the trench TR, the discontinuous area DCNT of each of the first inorganic insulating layer 120 and the second inorganic insulating layer 140 may be formed in the trench TR. In addition, the first extension portion 121 of the first inorganic insulating layer 120 which has been formed to have the step due to the presence of the first metal layer 110a may maintain the step shape even after the first metal layer 110a is removed as shown in FIG. 10. Further, the second extension portion 141 of the second inorganic insulating layer 140 which has been formed to have the step due to the presence of the first metal layer 110a and the second metal layer 137a may maintain the step shape even after the first metal layer 110a and the second metal layer 137a are removed as shown in FIG. 10. Therefore, in the discontinuous area DCNT in the trench TR, the first extension portion 121 may be formed to be spaced apart from the substrate 100 by a predetermined distance in the upward direction, while the second extension portion 141 may be formed to be spaced apart from the first extension portion 121 by a predetermined distance in the upward direction as shown in FIG. 10.

Referring to FIG. 11, the organic insulating layer 170 may be formed in the trench TR. The organic insulating layer 170 may be formed to have the stepped portion 171 recessed downwardly in a central area of the trench TR. In this case, the organic insulating layer 170 may be formed to cover the upper surface of the substrate 100 so as to continuously extend in the trench TR.

Each of the first extension portion 121 of the first inorganic insulating layer 120 and the second extension portion 141 of the second inorganic insulating layer 140 formed as described above may extend into the organic insulating layer 170. In some implementations, each of the end of the first inorganic insulating layer 120 and the end of the second inorganic insulating layer 140 may be formed to extend into the organic insulating layer 170 in the discontinuous area DCNT. For example, each of the first extension portion 121 and the second extension portion 141 may be positioned in the organic insulating layer 170 without extending through the organic insulating layer 170. In some implementations, each of the first extension portion 121 and the second extension portion 141 may extend only by a length sized such that each of the first extension portion 121 and the second extension portion 141 does not protrude out of the organic insulating layer 170. For example, the organic insulating layer 170 may be formed to have a sufficient thickness so as to cover the first extension portion 121 and the second extension portion 141 such that each of the first extension portion 121 and the second extension portion 141 does not extend into the stepped portion 171 of the organic insulating layer 170.

According to an implementation of the present disclosure as described above, as each of the first extension portion 121 of the first inorganic insulating layer 120 and the second extension portion 141 of the second inorganic insulating layer 140 extends into the organic insulating layer 170, the moisture permeation path ROU2 formed in the organic insulating layer 170 may be formed as a complicated path bypassing one or more of the first extension portion 121 and the second extension portion 141. Since each of the first extension portion 121 and the second extension portion 141 is formed to have the step only due to its own shape, the moisture permeation path ROU2 formed as the complicated path may be implemented at the interface with the organic insulating layer 170. Accordingly, this can have the effect of greatly elongating the moisture permeation path ROU2 in the organic insulating layer 170, and enhance the ability to cope with the moisture permeation of the display panel 10.

In addition, according to an implementation of the present disclosure, each of the first extension portion 121 of the first inorganic insulating layer 120 and the second extension portion 141 of the second inorganic insulating layer 140 may extend into the organic insulating layer 170, so that the organic insulating layer 170 may be engaged with and bonded to the first extension portion 121 and the second extension portion 141 via their complex structure. For example, since each of the first extension portion 121 and the second extension portion 141 is formed to extend to have the step, each of the first extension portion 121 and the second extension portion 141 may be fastened to the organic insulating layer 170 in a hook coupling manner. This may prevent the material of the organic insulating layer 170 from being loosened and lost even when an external force is applied to the display panel 10 or during a long-term operation of the display panel, thereby improving stability and durability of the display panel 10.

In addition, according to an implementation of the present disclosure, each of the first extension portion 121 of the first inorganic insulating layer 120 and the second extension portion 141 of the second inorganic insulating layer 140 may extend into the organic insulating layer 170, thereby allowing the inorganic layer and the organic layer made of different materials to be engaged with each other and bonded to each other. For example, when the inorganic layer and the organic layer are in contact with each other, the peel-off from each other may not easily occur, compared to when the inorganic layer and the inorganic layer are in contact with each other, or when the organic layer and the organic layer are in contact with each other. Accordingly, this can reduce the risk of removal of the inorganic layer and the organic layer from each other, and thus the organic insulating layer 170 may be prevented from being peeled off, thereby improving the stability and durability of the display panel 10.

In addition, according to an implementation of the present disclosure, each of the first extension portion 121 and the second extension portion 141 may be positioned in the organic insulating layer 170 without extending through the organic insulating layer 170, thereby forming an inorganic insulating barrier in a form trapped in the organic insulating layer 170. Accordingly, the moisture permeation path ROU2 in the organic insulating layer 170 may be elongated in a complex form such as a maze-like shape.

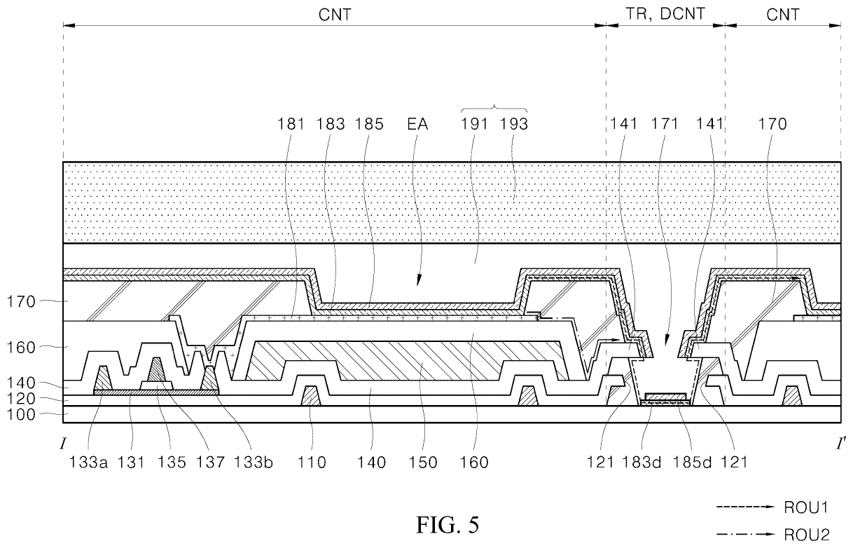

Referring back to FIGS. 5 to 7, at least one of the first extension portion 121 and the second extension portion 141 according to still another implementation of the present disclosure may be formed to extend through the organic insulating layer 170 and protrude out of the organic insulating layer 170.

Referring to FIG. 5, the first extension portion 121 may not protrude out of the organic insulating layer 170, but may be positioned inside the organic insulating layer 170. The second extension portion 141 may extend to protrude out of the organic insulating layer 170. In some implementations, the second extension portion 141 may extend more inwardly of the trench TR as compared to the first extension portion 121. Accordingly, the second extension portion 141 may serve substantially as an undercut portion.

In this case, the organic insulating layer 170 (e.g., a bank layer) may be discontinuous or broken in the trench TR. In some implementations, the upper surface of the substrate 100 positioned in the trench TR may be exposed to the outside without being covered with the organic insulating layer 170. Each of the light-emitting element layer 183 and the second electrode 185 stacked on the organic insulating layer 170 may also be discontinuous or broken in the trench TR. Each of the light-emitting element layer 183 and the second electrode 185 may be broken in the trench TR due to the presence of the second extension portion 141. Thus, a dummy light-emitting element layer 183d and a dummy second electrode 185d may be sequentially stacked on the substrate 100 in the trench TR. The dummy light-emitting element layer 183d may be discontinuous with the normal light-emitting element layer 183, and the dummy second electrode 185d may be discontinuous with the normal second electrode 185. In some implementations, each of the light-emitting element layer 183 and the second electrode 185 may be broken in the discontinuous area DCNT.

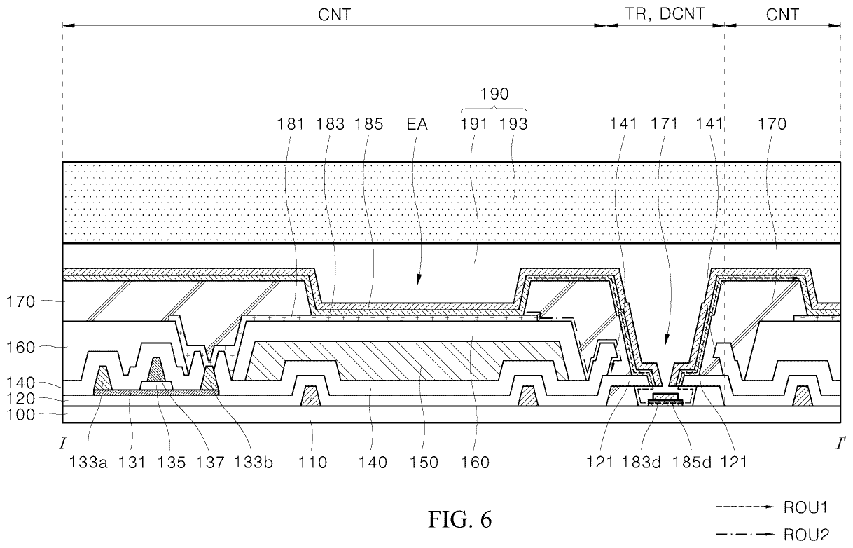

Referring to FIG. 6, the second extension portion 141 may be positioned inside the organic insulating layer 170 without protruding out of the organic insulating layer 170. The first extension portion 121 may extend to protrude out of the organic insulating layer 170. In some implementations, the first extension portion 121 may extend more inwardly of the trench TR than the second extension portion 141 may. Accordingly, the first extension portion 121 may serve substantially as an undercut portion.

In this case, the organic insulating layer 170 may be broken in the trench TR. In some implementations, the upper surface of the substrate 100 positioned in the trench TR may be exposed to the outside without being covered with the organic insulating layer 170. Each of the light-emitting element layer 183 and the second electrode 185 stacked on the organic insulating layer 170 may also be broken in the trench TR. Each of the light-emitting element layer 183 and the second electrode 185 may be broken in the trench TR due to the presence of the first extension portion 121. Thus, the dummy light-emitting element layer 183d and the dummy second electrode 185d may be sequentially stacked on the substrate 100 in the trench TR. The dummy light-emitting element layer 183d may be discontinuous with the normal light-emitting element layer 183, and the dummy second electrode 185d may be discontinuous with the normal second electrode 185. In some implementations, each of the light-emitting element layer 183 and the second electrode 185 may be broken in the discontinuous area DCNT.

Referring to FIG. 7, both the first extension portion 121 and the second extension portion 141 may extend to protrude out of the organic insulating layer 170. In some implementations, both the first extension portion 121 and the second extension portion 141 may extend inwardly of the trench TR. Accordingly, each of the first extension portion 121 and the second extension portion 141 may substantially serve as the undercut portion.

In this case, the organic insulating layer 170 may be broken in the trench TR. In some implementations, the upper surface of the substrate 100 positioned in the trench TR may be exposed to the outside without being covered with the organic insulating layer 170. Each of the light-emitting element layer 183 and the second electrode 185 stacked on the organic insulating layer 170 may also be broken in the trench TR. Each of the light-emitting element layer 183 and the second electrode 185 may be broken in the trench TR due to the presence of the first extension portion 121 and the second extension portion 141. Thus, the dummy light-emitting element layer 183d and the dummy second electrode 185d may be sequentially stacked on the substrate 100 in the trench TR. The dummy light-emitting element layer 183d may be discontinuous with the normal light-emitting element layer 183, and the dummy second electrode 185d may be discontinuous with the normal second electrode 185. In addition, the dummy light-emitting element layer 183d and the dummy second electrode 185d may be sequentially stacked on a portion of the first extension portion 121 protruding out of the organic insulating layer 170. In some implementations, each of the light-emitting element layer 183 and the second electrode 185 may be broken in the discontinuous area DCNT. In the case of the implementation according to FIG. 7, each of the light-emitting element layer 183 and the second electrode 185 may be broken twice or more due to the first extension portion 121 and the second extension portion 141.

As described above, according to an implementation of the present disclosure, at least one of the first extension portion 121 and the second extension portion 141 may extend through the organic insulating layer 170 and protrude out of the organic insulating layer 170, so that the organic insulating layer 170 may be broken in the trench TR. Accordingly, the light-emitting element layer 183 formed on the organic insulating layer 170 is also broken, such that the light-emitting element layer 183 may be broken in the trench TR, and thus the path ROU1 of the horizontal leakage current between the neighboring sub-pixels may be directly cut off.

Although some implementations of the present disclosure have been described above with reference to the accompanying drawings, the present disclosure may not be limited to some implementations and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some implementations as described above are not restrictive but illustrative in all respects.

What is claimed is:

1. A display panel comprising:
a substrate in which a plurality of sub-pixel areas corresponding to a plurality of sub-pixels are defined;
a first inorganic insulating layer disposed on the substrate;
a second inorganic insulating layer disposed on the first inorganic insulating layer;
a trench that penetrates through the first inorganic insulating layer and the second inorganic insulating layer, wherein the trench is arranged between adjacent sub-pixels among the plurality of sub-pixels; and
an organic insulating layer disposed on the second inorganic insulating layer and disposed in at least a portion of the trench,
wherein the first inorganic insulating layer includes a first extension portion that extends inward towards the trench through at least part of the organic insulating layer,
wherein the second inorganic insulating layer includes a second extension portion that extends inward towards the trench through at least part of the organic insulating layer.

2. The display panel of claim 1, wherein the first extension portion is raised above an adjacent portion of the first inorganic insulating layer and is upwardly spaced apart from the substrate by a first space between the first extension portion and the substrate.

3. The display panel of claim 2, wherein at least a portion of the first space between the first extension portion and the substrate is filled with the organic insulating layer.

4. The display panel of claim 1, wherein the second extension portion is raised above an adjacent portion of the second inorganic insulating layer and is upwardly spaced apart from the first extension portion by a second space between the second extension portion and the first extension portion.

5. The display panel of claim 4, wherein at least a portion of the second space between the second extension portion and the first extension portion is filled with the organic insulating layer.

6. The display panel of claim 1, wherein each of the first extension portion and the second extension portion are disposed within the organic insulating layer without extending through and disconnecting the organic insulating layer.

7. The display panel of claim 1, wherein the organic insulating layer continuously extends through the trench.

8. The display panel of claim 1, wherein the organic insulating layer includes a stepped portion that is recessed downwardly into the trench,
wherein a vertical level of a lowermost surface of the stepped portion is lower than a vertical level of a lowermost surface of the second extension portion.

9. The display panel of claim 8, wherein the display panel further comprises a light-emitting element layer disposed on the organic insulating layer, wherein the light-emitting element layer continuously extends on and along the stepped portion of the organic insulating layer so as to cover the trench.

10. The display panel of claim 1, wherein at least one of the first extension portion or the second extension portion extends into and through the organic insulating layer so as to protrude out of the organic insulating layer in the trench.

11. The display panel of claim 1, wherein the organic insulating layer is discontinuously disposed in the trench.

12. The display panel of claim 1, wherein the display panel further comprises a light-emitting element layer disposed on the organic insulating layer,
wherein the light-emitting element layer is discontinuously disposed in the trench.

13. The display panel of claim 12, wherein a continuity of the light-emitting element layer in the trench is disconnected by at least one of the first extension portion or the second extension portion.

14. The display panel of claim 12, wherein at least one dummy light-emitting element layer is further disposed in the trench and is discontinuous from the light-emitting element layer.

15. The display panel of claim 1, wherein the first inorganic insulating layer and the second inorganic insulating layer are in contact with the organic insulating layer.

16. A display panel comprising:
a substrate;
a buffer layer disposed on the substrate;
a circuit area disposed on the buffer layer;
a passivation layer disposed on the circuit area;
a first electrode disposed on the passivation layer;
a bank layer disposed on the first electrode and defining regions for a plurality of light emission areas;
a light-emitting element layer disposed on the bank layer; and
a second electrode disposed on the light-emitting element layer,
wherein a discontinuous area is positioned between adjacent light emission areas among the plurality of light emission areas, wherein each of the buffer layer and the passivation layer is discontinuous in the discontinuous area between the adjacent light emission areas,
wherein the bank layer is in contact with the buffer layer and the passivation layer in the discontinuous area.

17. The display panel of claim 16, wherein a first end portion of the buffer layer and a second end portion of the passivation layer each extends into the bank layer in the discontinuous area.

18. The display panel of claim 16, wherein a first end portion of the buffer layer and a second end portion of the passivation layer are positioned in the discontinuous area and are spaced apart from each other in a vertical direction.

19. The display panel of claim 16, wherein each of the light-emitting element layer and the second electrode continuously extends on and along the bank layer in the discontinuous area,
wherein a vertical level of a lowermost surface of a portion of each of the light-emitting element layer and the second electrode positioned in the discontinuous area is lower than a vertical level of a lowermost surface of a portion of the passivation layer positioned in the discontinuous area.

20. The display panel of claim 16, wherein each of the light-emitting element layer and the second electrode is discontinuous in the discontinuous area.

21. A display panel comprising:
a substrate on which a plurality of sub-pixels are defined;
a first inorganic insulating layer disposed on the substrate;
a second inorganic insulating layer disposed on the first inorganic insulating layer; and
an organic insulating layer disposed on the second inorganic insulating layer,
wherein a trench is disposed between adjacent sub-pixels and is recessed into the organic insulating layer to penetrate through the first inorganic insulating layer and the second inorganic insulating layer,
wherein the first inorganic insulating layer has a first undercut structure that extends toward an inside of the trench,
wherein the second inorganic insulating layer has a second undercut structure that extends toward the inside of the trench, and
wherein the organic insulating layer is disposed at least partially in the trench and fills spaces under the first undercut structure and under the second undercut structure.
